(19) United States
(12) Patent Application Publication
(10) Pub. No.: US 2026/0085888 A1
(43) Pub. Date: Mar. 26, 2026

(54) HEAT TREATMENT FURNACE WITH STABLE CONVEYANCE

(71) Applicant: SUZHOU NSINGLE INTELLIGENT TECHNOLOGY CO., LTD., Suzhou (CN)

(72) Inventors: Hui WANG, Suzhou (CN); Jianhui Tan, Suzhou (CN); Xiangrong Dai, Suzhou (CN); Xingchi Liu, Suzhou (CN)

(21) Appl. No.: 19/318,004

(22) Filed: Sep. 3, 2025

Related U.S. Application Data
(63) Continuation of application No. PCT/CN2025/079755, filed on Feb. 28, 2025.

(30) Foreign Application Priority Data
Sep. 23, 2024 (CN) 202411324553.2

(51) Int. Cl. F27B 9/02; F27B 9/30; F27D 3/00; F27D 99/00; H10F 71/00

(52) U.S. Cl. CPC F27B 9/028; F27B 9/3005; F27D 3/0084; F27D 99/0075; F27B 2009/3088; H10F 71/128

(57) ABSTRACT

The invention provides a heat treatment furnace with stable conveyance, including a furnace body, a conveyance mechanism, a carrier locking mechanism, and a carrier unlocking mechanism. The furnace body is provided with an isolation zone, a drying zone, and a cooling zone in a product conveyance direction. The isolation zone, the drying zone, and the cooling zone are jointly provided with a product channel which extends through the furnace body. The drying zone includes at least one drying box body. Circulating heating modules are symmetrically disposed on two sides of each drying box body. The conveyance mechanism includes a carrier bearing surface. The carrier locking mechanism is arranged on the carrier bearing surface, and is used for locking the carrier on the carrier bearing surface. The carrier unlocking mechanism is at least arranged at an outlet of the product channel, and used for releasing the locking of the carrier.

This application is a Continuation Application of PCT/CN2025/079755, filed on Feb. 28, 2025, which claims priority to Chinese Patent Application No. 202411324553.2, filed on Sep. 23, 2024, which is incorporated by reference for all purposes as if fully set forth herein.

### FIELD OF THE INVENTION

The present invention relates to the field of solar cell production technologies, and in particular, to a heat treatment furnace with stable conveyance.

### DESCRIPTION OF THE RELATED ART

A cassette-type drying furnace is a commonly used heat treatment device in the field of solar cell production. Typically, the cassette-type drying furnace mainly includes a furnace body, a conveyance device, and carriers. Carriers (e.g., cassettes or wafer boats) loaded with cells are conveyed through the furnace body via the conveyance device to perform heat treatment (drying or cooling) on the cells. However, most existing furnace bodies employ a single-pass hot air heating mode during drying. Due to a long single-pass path, insufficient negative pressure often leads to low thermal cycling efficiency and inconsistent drying times during actual drying. Additionally, during conveyance along the conveyance device, the carriers are prone to tilting or vibration, making the cells on the carriers susceptible to the risk of detachment or breakage.

### SUMMARY OF THE INVENTION

To overcome the foregoing disadvantages, an objective of the present invention is to provide a heat treatment furnace with stable conveyance, which improves drying efficiency, and can improve the stability of a carrier in a conveyance process.

To achieve the foregoing objective, the technical solution adopted in the present invention is a heat treatment furnace with stable conveyance, including:
a furnace body, where the furnace body is provided with an isolation zone, a drying zone, and a cooling zone in sequence in a product conveyance direction, the isolation zone, the drying zone, and the cooling zone are jointly provided with a product channel which extends through the furnace body, the drying zone includes at least one drying box body disposed in sequence, and circulating heating modules used for heating the product channel are symmetrically disposed on two sides of each drying box body; a conveyance mechanism, used for conveying a product in the product channel, where the conveyance mechanism includes a carrier bearing surface used for bearing a carrier, and the carrier is loaded with at least one product;
a carrier locking mechanism, arranged on the carrier bearing surface, and used for locking the carrier on the carrier bearing surface; and
a carrier unlocking mechanism, at least arranged at an outlet of the product channel, and used for releasing the locking of the carrier by the carrier locking mechanism.

The beneficial effects of the heat treatment furnace with stable conveyance of the present invention are as follows:

In the drying zone, the circulating heating modules are respectively disposed on two sides of the drying box body, so that dual-path circulating heating can be performed on the product in the product channel, thereby improving the drying effect of the product. Compared with a single-pass heating mode in existing technologies, the two circulating heating modules are disposed, so that airflow circulating paths between the circulating heating modules and the product channel can be shortened, thereby improving thermal circulating efficiency. The carrier locking mechanism is disposed, so that in the process of conveying the carrier along with the conveyance mechanism along the product channel, the carrier can be locked on the conveyance mechanism, thereby improving the stability of the carrier on the conveyance mechanism, and further ensuring the conveyance stability of the product on the carrier. The carrier unlocking mechanism is disposed, so that the locking between the carrier and the conveyance mechanism can be unlocked at the outlet of the product channel, thereby facilitating the disengagement of the carrier from the conveyance mechanism.

Further, each of the circulating heating modules includes a heating chamber, a circulating air passage, and a suction assembly, a heating member is provided in the heating chamber, and the circulating air passage is used for connecting the heating chamber and the product channel; and the suction assembly is arranged at a top of the heating chamber, and is used for suctioning the heating chamber, to enable airflow in the heating chamber to circulate in the circulating air passage and the product channel. The circulating air passage is disposed to enable the heating chamber to be in independent communication with the product channel, and the suction assembly is disposed to enable airflow circulation between the heating chamber and the product channel. When the heating members and the suction assemblies of the two circulating heating modules operate simultaneously, a dual-path circulating heating mode of the product channel can be achieved.

The heating chambers and the suction assemblies of the two circulating heating modules can shorten an airflow circulating path between a single heating chamber and the product channel. This is equivalent to that each heating chamber only needs to perform circulating heating for a half of space in the product channel in the drying zone. Therefore, a power requirement of the suction assembly can be reduced, thereby ensuring the stability of negative pressure in a single airflow circulating path. Further, the circulating air passage includes a first air passage and a second air passage that are used cooperatively, the first air passage extends through a side wall of the drying box body, and the second air passage is sandwiched between an inner bottom wall and an outer bottom wall of the drying box body; and when the suction assembly is started, the first air passage guides the corresponding airflow in the heating chamber into the product channel, and the second air passage recirculates the airflow in the product channel into the corresponding heating chamber. Through the cooperation of the first air passage and the second air passage, a path for airflow communication can be formed between the side wall and a bottom wall of the drying box body, thereby enabling hot airflow that enters the product channel through the first air passage to fully contact the product in the product channel.

Further, two second air passages are separated by a partition plate, a recirculation opening in communication with the two second air passages is opened on an inner bottom wall of the drying box body, the recirculation opening is covered with a second mesh plate which is fixedly connected to the inner bottom wall of the drying box body, the partition plate is disposed vertically, and an upper end of the partition plate is connected to a middle of the second mesh plate. The partition plate is disposed, so that the independent operation of the two second air passages can be ensured, thereby preventing airflow cross-flow between the two second air passages. The recirculation opening is disposed, so that airflow in the drying channel can be guided into the second air passage.

Further, the carrier locking mechanism includes a plurality of locking portions arranged on the carrier bearing surface in the product conveyance direction, each of the locking portions includes locking assemblies symmetrically disposed in a direction perpendicular to the product conveyance direction, each of the locking assemblies includes a locking block, an elastic member, and a movable member, the movable member is reciprocally movable in the direction perpendicular to the product conveyance direction, the locking block is connected to a side of the movable member that faces the carrier, the elastic member is located on a side of the locking block that is away from the carrier, one end of the elastic member abuts against the locking block, and the other end of the elastic member is fixed on the carrier bearing surface; and when the locking block abuts against the carrier, the elastic member is in a compressed state.

Through the movement of the movable members of the two locking assemblies, the two locking blocks can be simultaneously driven to move toward or away from the carrier, thereby achieving the locking or unlocking of the carrier. The elastic members in a compressed state are then disposed to enable the locking blocks to elastically press against the carrier, thereby ensuring the locking of the carrier and avoiding damage to the surface of the carrier due to rigid pressing.

Further, the locking assembly further includes a mounting base, and the mounting base is fixedly connected to the conveyance mechanism, and a guide slot extends through the mounting base; the movable member includes a pull rod passing through the guide slot, and an end of the pull rod that faces the carrier is connected to the locking block; and the elastic member includes a spring sleeved over the pull rod, one end of the spring abuts against the locking block, and the other end of the spring abuts against the mounting base. The mounting base and the guide slot are disposed to guide the movement direction of the pull rod, thereby ensuring the accuracy of the locking direction of the locking block.

Further, a locking protrusion is provided on a side of the locking block that faces the carrier; when the locking block abuts against the carrier, a lower end surface of the locking protrusion also abuts against the carrier; and the lower end surface of the locking protrusion is a downward-arching arc-shaped surface. The locking protrusions are disposed to cooperate with the locking blocks to abut against the carrier at multiple positions and in different directions, thereby enhancing the locking stability of the carrier. In addition, the lower end surface of the locking protrusion is disposed as the downward-arching arc-shaped surface to enable the contact between the locking protrusion and the carrier to be line contact, thereby minimizing the friction between the locking protrusion and the carrier.

Further, the carrier unlocking mechanism includes unlocking assemblies symmetrically disposed on the conveyance mechanism in the direction perpendicular to the product conveyance direction, each of the unlocking assemblies includes a plate body arranged in the product conveyance direction, and an unlocking surface capable of pressing against the movable member is provided on a side of the plate body that is away from the carrier; and when the carrier reaches the carrier unlocking mechanism, the movable member is movable away from the carrier under the action of the unlocking surface, to disengage the locking block from the carrier. Through the limiting and abutting of the unlocking surface, the movable member can be forced to move away from the carrier, to disengage the locking block from the carrier, thereby achieving the unlocking of the carrier.

Further, a carrier recirculation mechanism used for conveying the carrier is provided below the furnace body, and a lifting mechanism used for lifting the carrier onto the conveyance mechanism is provided between the conveyance mechanism that is close to an inlet of the product channel and the carrier recirculation mechanism.

Further, the furnace body is further provided with a dust collection mechanism located between the conveyance mechanism and the carrier recirculation mechanism, the dust collection mechanism includes a dust case with an opening upwards, the dust case extends in the product conveyance direction, and a width of the dust case is greater than a width of the conveyance mechanism. The dust collection mechanism is disposed, so that dust that falls off the conveyance mechanism can be received, to keep dust from falling on the carrier recirculation mechanism, thereby avoiding contamination to the carrier.

Further, a transfer roller set used for bearing the carrier is provided close to an inlet of the product channel, the transfer roller set includes at least two transfer rollers, upper end surfaces of all the transfer rollers are located in a same plane, and the upper end surface of the transfer roller closest to the inlet of the product channel is flush with an end surface for bearing the carrier of the conveyance mechanism. The delivery of the carrier by the transfer roller set can perform transition buffering on the carrier that enters the conveyance mechanism.

Preferably, a thermal conductive member is connected to a side wall of the product channel, the thermal conductive member is located in the isolation zone and/or the cooling zone, and the thermal conductive member is connected to a ventilation duct extending toward the drying zone.

Preferably, an air curtain is connected to a side wall of the product channel, the air curtain is provided with an internal channel, the air curtain is further provided with a ventilation opening in a radial direction of the product channel, the ventilation opening is in communication with the internal channel, an air blowing member is further connected to the air curtain, and an output end of the air blowing member is in communication with the internal channel.

### BRIEF DESCRIPTION OF THE DRAWINGS

FIG. 1 is a three-dimensional schematic structural diagram of a heat treatment furnace according to an embodiment of the present invention;

FIG. 2 is a partial enlarged view of a part A in FIG. 1;

FIG. 3 is a three-dimensional schematic structural diagram of a furnace body according to an embodiment of the present invention;

FIG. 4 is a schematic cross-sectional view of a drying box body according to an embodiment of the present invention;

FIG. 5 is a three-dimensional schematic structural diagram of a drying box body according to an embodiment of the present invention;

FIG. 6 is a schematic structural diagram of a carrier being placed on a conveyance mechanism according to an embodiment of the present invention;

FIG. 7 is a partial enlarged view of a part B in FIG. 6;

FIG. 8 is a schematic structural diagram of cooperation between a carrier locking mechanism and a carrier unlocking mechanism according to an embodiment of the present invention;

FIG. 9 is a side view of a furnace body according to an embodiment of the present invention;

FIG. 10 is a partial enlarged view of a part C in FIG. 9; and

FIG. 11 is a schematic structural diagram of a dust case according to an embodiment of the present invention;

FIG. 12 is a partial enlarged view of a part D in FIG. 1.

FIG. 13 is a assembly diagram of a thermal conductive member according to an embodiment of the present invention.

FIG. 14 is a partial enlarged view of a part E in FIG. 13.

FIG. 15 is a schematic structural diagram of a thermal conductive member according to an embodiment of the present invention.

FIG. 16 is a assembly diagram of an air curtain and an air blowing member according to an embodiment of the present invention;

FIG. 17 is a schematic structural diagram of an air curtain and an air blowing member according to an embodiment of the present invention; and

FIG. 18 is a schematic structural diagram of another embodiment of a locking assembly.

### IN THE DRAWINGS

1—furnace body; 11—isolation zone; 12—drying zone; 121—drying box body; 1211—recirculation opening; 1212—exhaust port; 122—circulating heating module; 1221—heating chamber; 1222—suction assembly; 1223—heating member; 1224—first air passage; 1225—second air passage; 123—first mesh plate; 124—second mesh plate; 125—partition plate; 13—cooling zone; 131—exhaust vent; 14—product channel; 15—side baffle; 16—air curtain; 161—ventilation opening; 17—air blowing member;
2—conveyance mechanism; 21—conveyance rack; 22—closed-loop chain; 23—support plate;
3—carrier locking mechanism; 31—locking block; 311—locking protrusion; 32—elastic member; 33—movable member; 331—pull rod; 332—vertical rod; 333—magnet; 34—mounting base; 341—obround slot;
4—carrier unlocking mechanism; 41—plate body; 411—unlocking inclined surface; 412—pressing flat surface;
5—carrier;
6—transfer roller set;
7—carrier recirculation mechanism;
81—dust case; 811—case body; 812—connecting plate; 813—support cover plate; 82—mounting plate; 821—support rod; and
9—thermal conductive member; 91—ventilation duct.

### DETAILED DESCRIPTION OF THE PREFERRED EMBODIMENTS

The preferred embodiments of the present invention are described below in detail with reference to the accompanying drawings, so that the advantages and features of the present invention may be more readily understood by those skilled in the art, thereby defining the scope of protection of the present invention more clearly and explicitly.

### EMBODIMENT

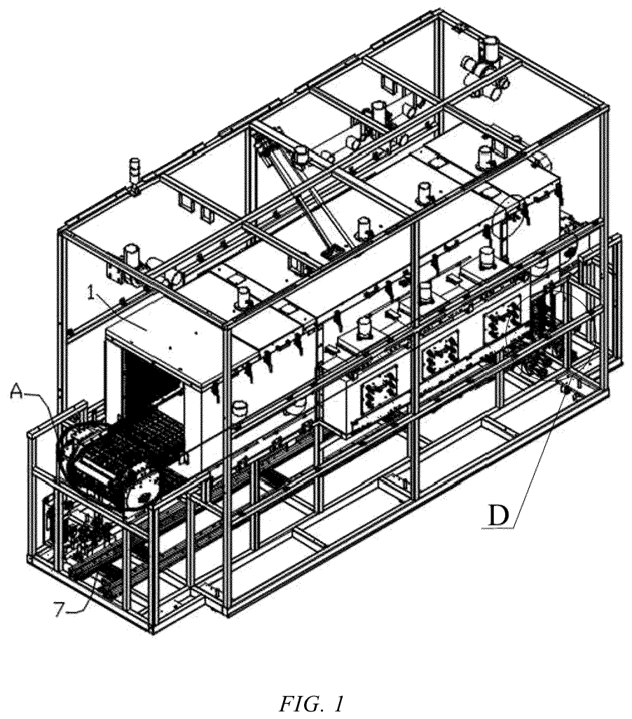

Referring to FIGS. 1-3 to FIG. 12, a heat treatment furnace with stable conveyance of the present invention includes a furnace body 1, a conveyance mechanism 2, a carrier locking mechanism 3, and a carrier unlocking mechanism 4. The furnace body 1 is provided with an isolation zone 11, a drying zone 12, and a cooling zone 13 in sequence in a product conveyance direction. The isolation zone 11, the drying zone 12, and the cooling zone 13 are jointly provided with a product channel 14 which extends through the furnace body 1. The drying zone 12 includes at least one drying box body 121 disposed in sequence. Circulating heating modules 122 used for heating the product channel are symmetrically disposed on two sides of each drying box body. The conveyance mechanism 2 is used for conveying a product in the product channel 14. The conveyance mechanism 2 includes a carrier bearing surface used for bearing a carrier 5. The carrier 5 is loaded with at least one product. The carrier locking mechanism 3 is arranged on the carrier bearing surface, and is used for locking the carrier 5 on the carrier bearing surface. The carrier unlocking mechanism 4 is at least arranged at an outlet of the product channel 14, and is used for releasing the locking of the carrier 5 by the carrier locking mechanism 3.

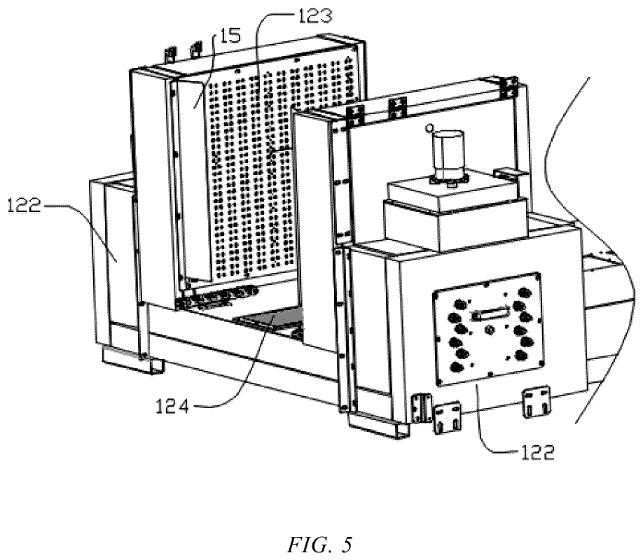

Specifically, referring to FIG. 4 and FIG. 5, each of the circulating heating modules 122 includes a heating chamber 1221, a circulating air passage, and a suction assembly 1222 (suction fan). A heating member 1223 is provided in the heating chamber 1221. The circulating air passage is used for connecting the heating chamber 1221 and the product channel 14. The suction assembly 1222 is arranged at a top of the heating chamber 1221, and is used for suctioning the heating chamber 1221, to enable airflow in the heating chamber 1221 to circulate in the circulating air passage and the product channel 14.

During operation, a product (silicon wafer) is loaded onto the carrier 5 at an inlet of the product channel 14, and the carrier 5 is locked on the conveyance mechanism 2 through the carrier locking mechanism 3. The conveyance mechanism 2 is started to enable the carrier 5 loaded with the product to sequentially pass through the isolation zone 11, the drying zone 12, and the cooling zone 13 along the product channel 14 to perform isolation, drying, and cooling on the product. In the drying zone 12, the at least one drying box body 121 is disposed, so that the product can be continuously dried, thereby improving the drying efficiency of the product. The circulating heating modules 122 are respectively disposed on two sides of the drying box body 121, and the heating chamber 1221, the circulating air passage, and the suction assembly 1222 of each circulating heating module 122 can perform independent airflow circulation with the product channel 14. When the heating member 1223 in the heating chamber 1221 operates, hot airflow in the heating chamber 1221 can enter the product channel 14 along the circulating air passage under the action of the suction assembly 1222, to perform a drying operation on the product in the product channel 14. When the carrier 5 loaded with the product reaches the outlet of the product channel 14, the carrier unlocking mechanism 4 may release the locking between the carrier and the conveyance mechanism 2, thereby facilitating the disengagement of the carrier 5 from the conveyance mechanism 2.

In some embodiments, the circulating air passage includes a first air passage 1224 and a second air passage 1225 that are used cooperatively. The first air passage 1224 extends through a side wall of the drying box body 121. The second air passage 1225 is sandwiched between an inner bottom wall and an outer bottom wall of the drying box body 121. When the suction assembly 1222 is started, the first air passage 1224 uniformly guides the corresponding airflow in the heating chamber 1221 into the product channel 14, and the second air passage 1225 recirculates the airflow in the product channel 14 into the corresponding heating chamber 1221.

When the heating member 1223 in the heating chamber 1221 operates, the temperature in the heating chamber 1221 rises accordingly. In this case, along with the suction by the suction assembly 1222, the hot airflow in the heating chamber 1221 can enter the product channel 14 along the first air passage 1224 to dry the product in the product channel 14. Subsequently, in the product channel 14, airflow that has exchanged heat with the product recirculates into the heating chamber 1221 via the second air passage 1225 at the bottom of the product channel 14 to be heated again. In this way, the circulation of airflow between the heating chamber 1221 and the product channel 14 is formed. The circulation of airflow can ensure the stability of the temperature in the product channel 14, thereby ensuring the uniform heating of the product, thereby improving the drying effect of the product. In addition, the first air passage 1224 is located in the side wall of the drying box body 121 and the second air passage 1225 is located in the bottom wall of the drying box body 121. In the process of airflow circulation, a path for airflow communication can be formed between the side wall and the bottom wall of the drying box body 121, and the path is halved compared with the path of a single-pass heating module. For circulating airflow with the same volume, the circulating frequency is increased, to continuously perform temperature compensation for the heating chamber, thereby replenishing the heat carried away by the product through the temperature zone, and further enabling hot airflow that enters the product channel 14 through the first air passage 1224 to fully contact the product in the product channel 14.

In some embodiments, referring to FIG. 5, a first mesh plate 123 covering the first air passage 1224 is arranged on each of two inner side walls of the drying box body 121. The first mesh plate 123 is arranged vertically. The airflow that enters the drying box body 121 via the first air passage 1224 can be distributed via the first mesh plate 123 to enter the product channel 14, thereby ensuring that uniform dispersion of hot airflow in the first air passage 1224 into the product channel 14, reducing temperature differences in the product channel 14, and making a maximum temperature difference between different positions of the product not higher than ±5° C.

In some embodiments, referring to FIG. 4, a recirculation opening 1211 in communication with the two second air passages 1225 is opened in an inner bottom wall of the drying box body 121, the recirculation opening 1211 is covered with a second mesh plate 124 which is fixedly connected to the inner bottom wall of the drying box body 121, the partition plate is disposed vertically. The airflow in the product channel 14 can enter the second air passage 1225 via the recirculation opening 1211, and the second mesh plate 124 can uniformly distribute the airflow.

Furthermore, to ensure the independence of the two second air passages 1225, the second air passages 1225 are arranged in a horizontal direction, and a partition plate 125 is disposed between the two second air passages 1225. The partition plate 125 is arrange vertically. An upper end of the partition plate 125 is connected to a middle of the second mesh plate 124, and a lower end of the partition plate 125 is connected to the drying box body 121. The partition plate 125 is disposed, so that the independent operation of the two second air passages 1225 is ensured, thereby preventing airflow flowing between the two second air passages 1225. In addition, because the partition plate 125 is connected to the middle of the second mesh plate 124, after the airflow in the product channel 14 is distributed by the second mesh plate 124, airflow distributed on one side of the partition plate 125 can enter one second air passage 1225 located on the same side of the partition plate 125 as the airflow, and airflow distributed to the other side of the partition plate 125 can enter the other second air passage 1225 located on the same side of the partition plate 125 as the airflow.

In some embodiments, to reduce heat losses in the flowing process of airflow, thermal insulation cotton layers are wrapped on inner walls of both the first air passage 1224 and the second air passage 1225.

In the drying process, exhaust gas is generated in the product channel 14 of the drying zone 12. To discharge the exhaust gas, in some embodiments, referring to FIG. 4, an exhaust port 1212 in communication with the product channel 14 is opened at the top of the drying box body 121, and a check valve is provided at the exhaust port 1212. The check valve can only open away from the product channel 14, to keep external gas from entering the product channel 14 through the exhaust port 1212.

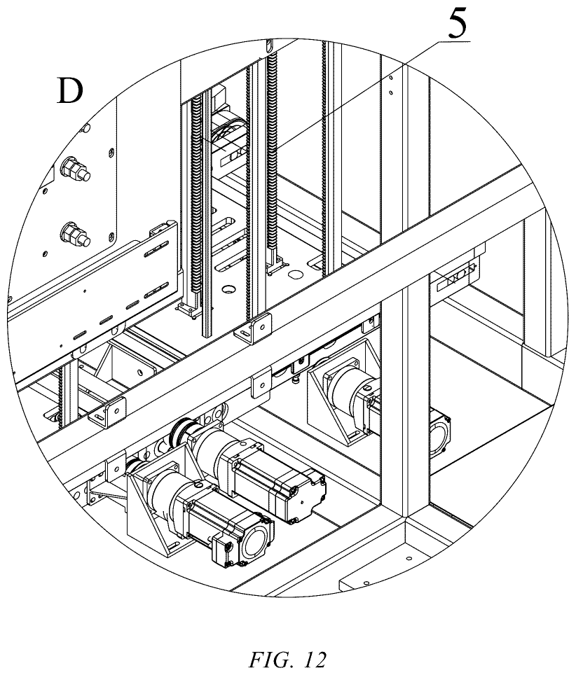

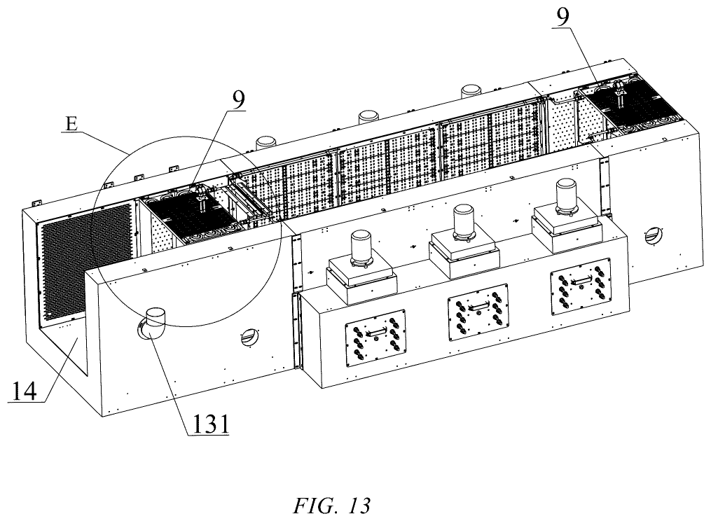

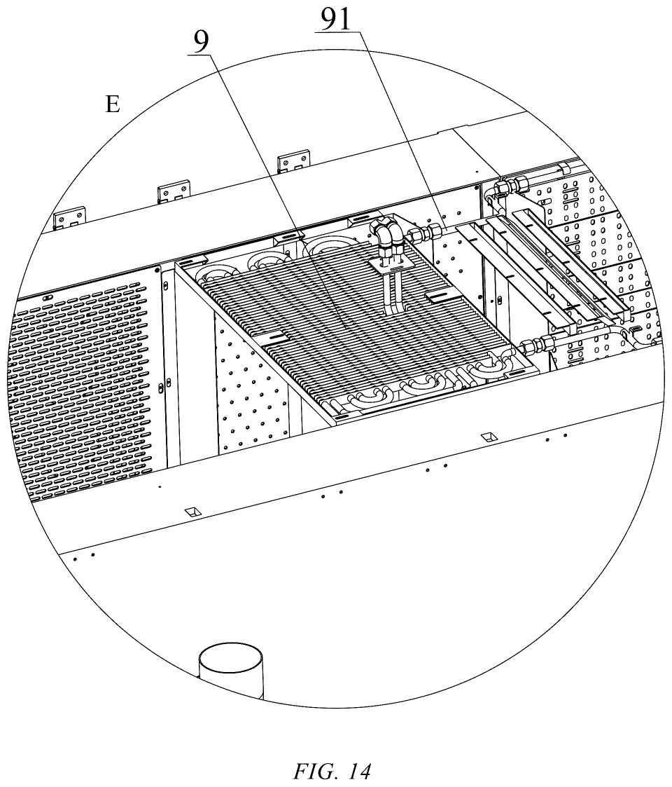

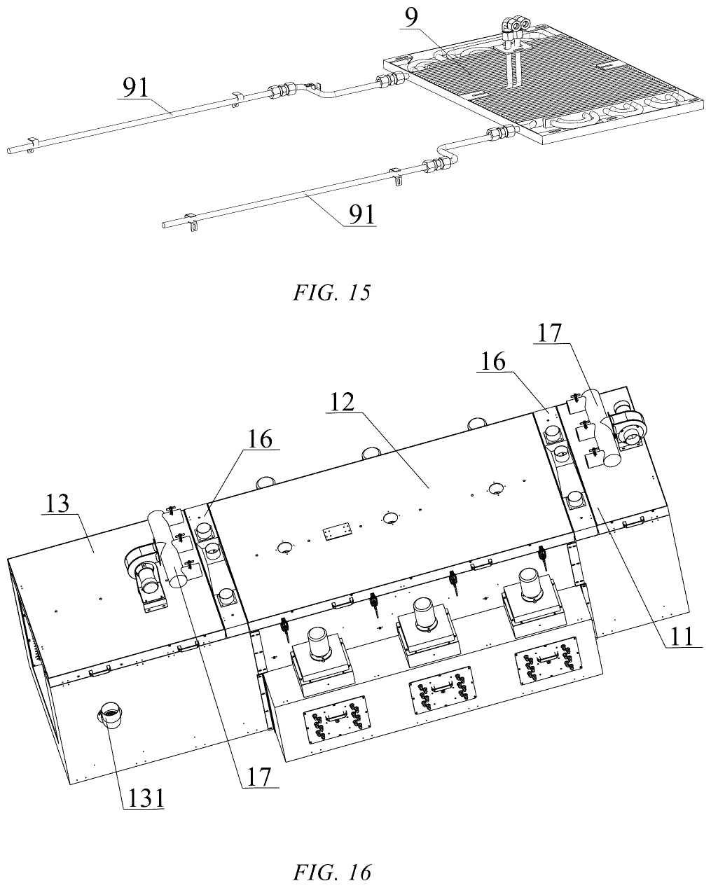

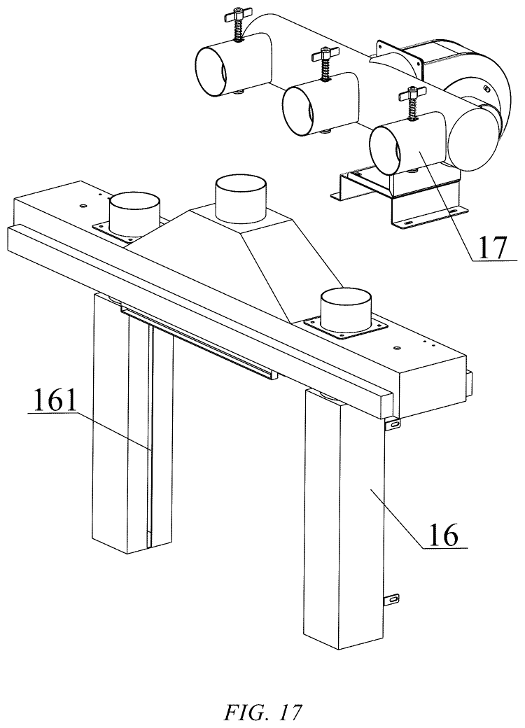

Referring to FIG. 13-15, in some embodiments, a thermal conductive member 9 is connected to the top of the product channel 14. Specifically, the thermal conductive member 9 is located in the isolation zone 11 and/or the cooling zone 13. FIG. 12 shows the thermal conductive member 9 located in the isolation zone 11. The thermal conductive member 9 is connected to two ventilation ducts 91 that extend toward the drying zone 12. One of the ventilation ducts 91 is connected to an external air compressor, and the other ventilation duct 91 is in communication with the drying zone 12. The air compressor can make gas in the thermal conductive member 9 flow to the ventilation duct 91, and the gas flows to the drying zone 12 through the ventilation duct 91. The thermal conductive member 9 is disposed, so that high-temperature gas that flows to the isolation zone 11 and the cooling zone 13 in the drying zone 12 can exchange heat with the thermal conductive member 9, to increase the temperature of the gas in the thermal conductive member 9. The air compressor makes the high-temperature gas flow to the drying zone 12, to reduce heat losses in the drying zone 12, thereby achieving energy saving and consumption reduction. Referring to FIG. 16-17, in some embodiments, an air curtain 16 is connected to a side wall of the product channel 14. The air curtain 16 is located at a connection position between the drying zone 12 and the isolation zone 11. The air curtain 16 is further located at a connection position between the drying zone 12 and the cooling zone 13. The air curtain 16 is provided with a communication channel for the passage of the carrier 5 and gas. The air curtain 16 is disposed, so that a radial area of the product channel 14 can be reduced, thereby blocking of part of high-temperature gas that is located in the drying zone 12 from overflowing. The air curtain 16 is further connected to an air blowing member 17. The air blowing members 17 of two air curtains 16 are disposed opposite to each other. FIG. 13 shows the air curtain 16 located between the drying zone 12 and the isolation zone 11. The air curtain 16 is provided with an internal channel. A ventilation opening 161 disposed in a radial direction of the product channel 14 is provided on an opposite side of the air curtain 16. The ventilation opening 161 is located in a side wall of the communication channel, and the ventilation opening 161 is in communication with the internal channel. An output end of the air blowing member 17 is in communication with the internal channel. The air blowing member 17 blows air to enable the ventilation opening 161 to output airflow, to further block high-temperature gas located in the drying zone 12 from overflowing, thereby reducing heat losses in the drying zone 12, and achieving energy saving and consumption reduction. In addition, temperature differences in a vertical direction in the drying zone 12 can be small, and temperature differences at the position of the air curtain 16 in the vertical direction in the product channel 14 are small, thereby avoiding different drying effects of the product in the vertical direction in the drying zone 12.

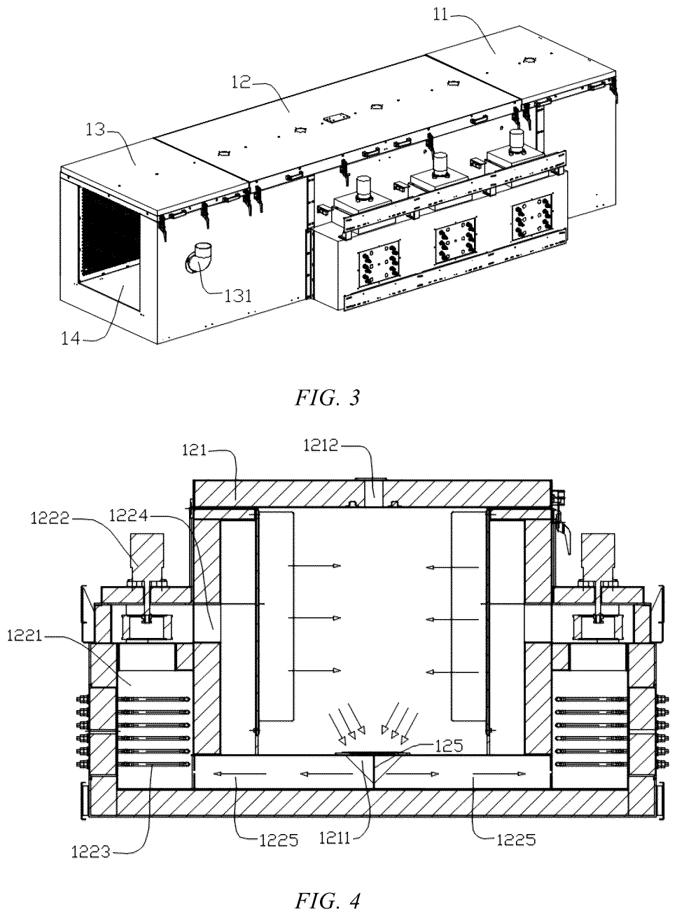

In some embodiments, referring to FIG. 3, the cooling zone 13 includes a cooling box body. A cooling fan and an exhaust vent 131 in communication with the product channel are respectively provided on two sides of the cooling box body in a direction perpendicular to the product conveyance direction. The cooling fan sucks external cold air into the product channel 14 located in the cooling zone 13 to cool the product in the product channel 14, and then the gas in the product channel 14 can be discharged through the exhaust vent 131, thereby ensuring that external cold air can continuously enter the product channel 14 through the cooling fan. Furthermore, a side baffle 15 is provided at each of boundaries between the isolation zone 11, the drying zone 12, and the cooling zone 13 to guide airflow, thereby reducing airflow cross-flow in different zones.

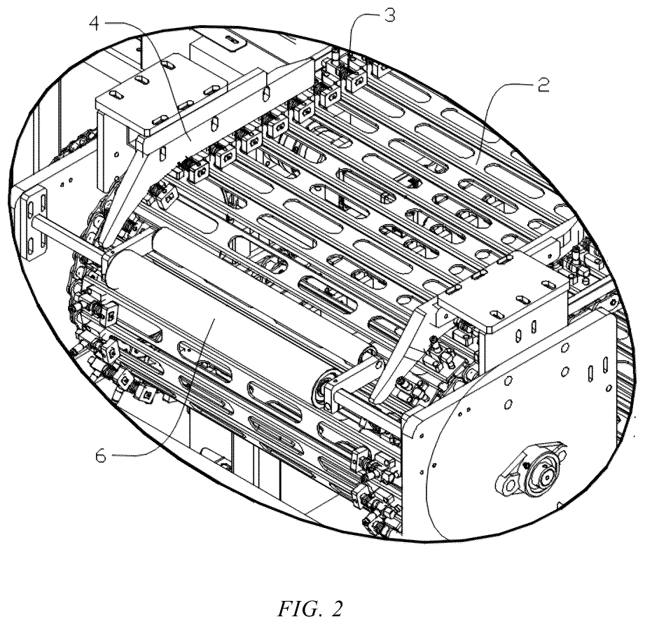

In some embodiments, referring to FIGS. 2, 6, 9, and 10, the conveyance mechanism 2 includes a drive roller and a driven roller mounted on a conveyance rack 21. The driven roller and the drive roller are wrapped together with two closed-loop chains 22 arranged side by side. A plurality of support plates 23 are uniformly arranged between the two closed-loop chains 22 in the product conveyance direction. An outward-facing side of the support plate 23 forms the carrier bearing surface used for bearing the carrier 5. In addition, the conveyance rack 21 is provided with a conveyance drive assembly (e.g., a motor) connected to the drive roller.

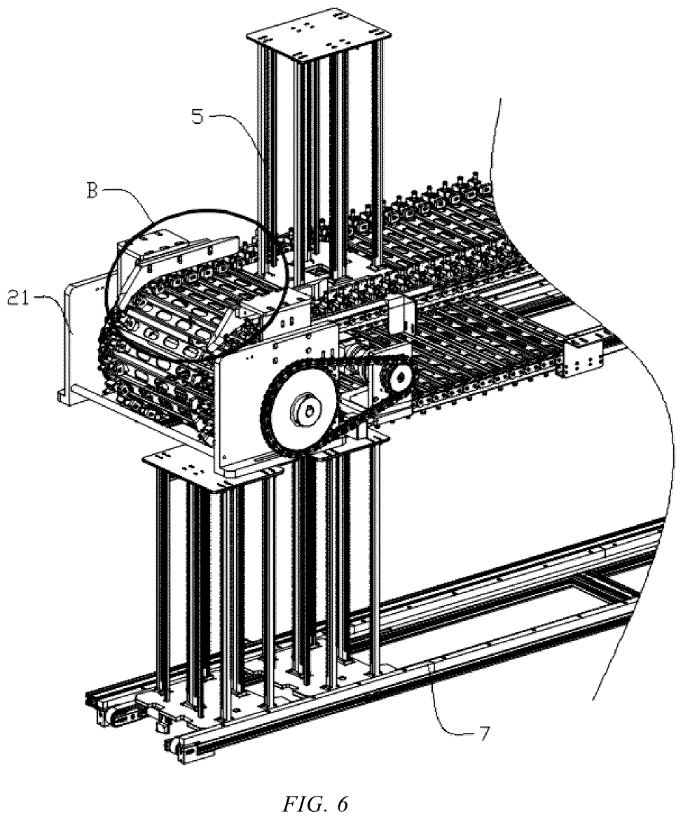

Referring to FIG. 6 to FIG. 8, the carrier locking mechanism 3 includes a plurality of locking portions arranged on the support plate 23 in the product conveyance direction. Each of the locking portions includes locking assemblies symmetrically disposed in a direction perpendicular to the product conveyance direction. Each of the locking assemblies includes a locking block 31, an elastic member 32, and a movable member 33. The movable member 33 is reciprocally movable in the direction perpendicular to the product conveyance direction. The locking block 31 is connected to a side of the movable member 33 that faces the carrier 5. The elastic member 32 is located on a side of the locking block 31 that is away from the carrier 5. One end of the elastic member 32 abuts against the locking block 31, and the other end of the elastic member 32 is fixed on the support plate 23. When the locking block 31 abuts against the carrier 5, the elastic member 32 is in a compressed state.

In the process of conveying the product and the carrier, the locking portions can be synchronously conveyed with the product and the carrier 5. When the carrier 5 is placed on the carrier bearing surface, through the cooperation of the two locking assemblies, the two locking blocks 31 are enabled to simultaneously to move toward or away from the carrier 5, thereby achieving the limiting and locking or unlocking of the carrier 5. When the locking blocks 31 abut against the carrier 5, the elastic member 32 in a compressed state can ensure the locking of the carrier 5 by the locking blocks 31 and also avoid damage to the surface of the carrier 5 due to rigid pressing.

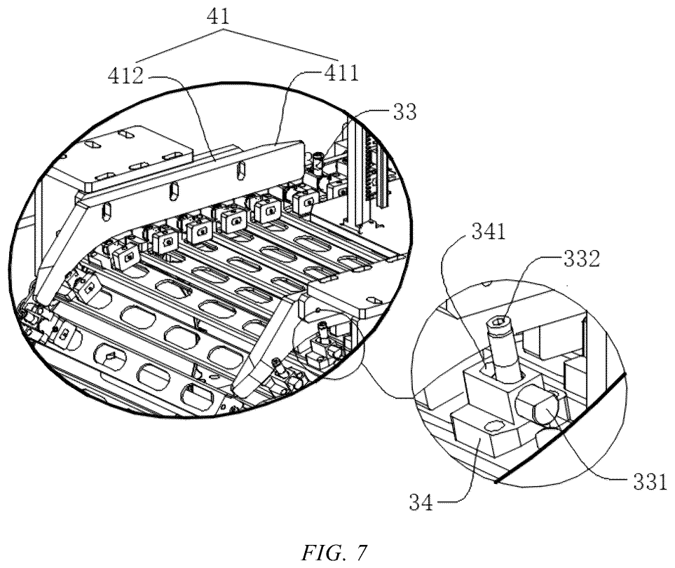

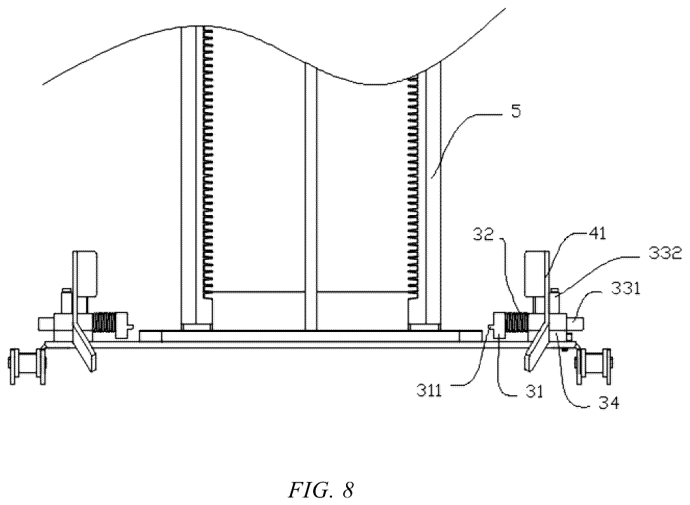

The number of the locking portions may be set the same as the number of the support plates 23, and the locking portions are disposed on the support plate 23 in a one-to-one correspondence. Alternatively, the number of the support plates 23 may be multiple times greater than the number of the locking portions, and the plurality locking portions are uniformly disposed at intervals on the plurality of support plates 23. Regardless of the setting of the number of the locking portions, it needs to be ensured that a spacing between two adjacent locking portions is less than the size of the carrier 5 in the product conveyance direction, so that when the carrier 5 is placed on the conveyance mechanism 2, at least one locking portion can lock the carrier 5. In some embodiments, referring to FIG. 7 and FIG. 8, the locking assembly further includes a mounting base 34. The mounting base 34 is fixedly connected on the support plate 23, and a guide slot extends through the mounting base and arranged in the direction perpendicular to the product conveyance direction. The movable member 33 includes a pull rod 331 passing through the guide slot, and an end of the pull rod 331 that faces the carrier 5 is connected to the locking block 31. The locking block 31 is suspended, and an end of the locking block 31 that is away from the pull rod 331 is used for abutting against the carrier 5.

Furthermore, the elastic member 32 includes a spring sleeved over the pull rod, one end of the spring abuts against the locking block 31, and the other end of the spring abuts against the mounting base 34. Because the mounting base 34 is fixedly connected to the support plate 23, when an external force pulls the pull rod 331 to move away from the carrier 5, the locking block 31 can move synchronously, thereby compressing the spring. When the external force is removed, the locking block 31 can move toward the carrier under the reset action of the spring, thereby achieving the locking of the carrier 5.

To ensure that the spring remains in a compressed state, in some embodiments, an obround slot 341 in communication with the guide slot is opened at an upper end of the mounting base 34. A vertical rod 332 passable through the obround slot 341 is fixedly disposed on the pull rod 331. When the vertical rod 332 moves in the obround slot 341, the spring remains in a compressed state. In addition, when the vertical rod 332 reaches an end of the obround slot 341 that is close to the carrier 5, the locking block 31 can lock the carrier 5. When the vertical rod 332 reaches an end of the obround slot 341 that is away from the carrier 5, the locking block 31 cannot lock the carrier 5. The obround slot 341 is provided to limit the movement range of the vertical rod 332, thereby indirectly limiting the movement range of the pull rod 331 and the locking block 31.

In some embodiments, a locking protrusion 311 is provided on a side of the locking block 31 that faces the carrier. When the locking block 31 abuts against the carrier 5, a lower end surface of the locking protrusion 311 also abuts against the carrier 5, so that the carrier 5 is restricted in a vertical direction. Furthermore, the lower end surface of the locking protrusion 311 is a downward-arching arc-shaped surface, thereby minimizing the friction between the locking protrusion 311 and the carrier 5. In some embodiments, referring to FIG. 7 and FIG. 8, the carrier unlocking mechanism 4 includes unlocking assemblies symmetrically disposed on the conveyance mechanism 2 in the direction perpendicular to the product conveyance direction. Each of the unlocking assemblies includes a plate body 41 arranged in the product conveyance direction. The plate body 41 is fixedly connected to the conveyance rack 21, and is suspended above the support plate 23. An unlocking surface capable of pressing against the movable member 33 is provided on a side of the plate body 41 that is away from the carrier 5. Specifically, the unlocking surface includes an unlocking inclined surface 411 and a pressing flat surface 412 that are continuously disposed in the product conveyance direction, the unlocking inclined surface 411 is located at an end of the pressing flat surface 412 that is away from the outlet of the product channel, and the unlocking inclined surface 411 gradually tilts away from the carrier 5 from an end that is far away from the pressing flat surface 412 to an end that is close to the pressing flat surface 412, to enable the vertical rod 332 to drive the locking block 31 to move away from the carrier 5 when the vertical rod 332 moves along the unlocking inclined surface 411 toward the pressing flat surface 412.

During actual arrangement, the height of a lower end surface of the plate body 41 should be greater than the height of the upper end surface of the mounting base 34, thereby ensuring that when the vertical rod 332 moves along an unlocking surface of the plate body 41, the mounting base 34 can pass through from below the plate body 41. Additionally, to ensure that the vertical rod 332 can smoothly abut against the unlocking inclined surface 411, and an end of the unlocking inclined surface 411 that is away from the pressing flat surface 412 should be disposed closer to the carrier 5 than the vertical rod 332 in a locked state (in the locked state, the locking block 31 is pressed against the carrier 5, and the vertical rod 332 is located at the end of the obround slot 341 that is close to the carrier 5). When the vertical rod 332 in the locked state reaches the unlocking assembly, the vertical rod 332 can directly abut against the unlocking inclined surface 411, and in a process of the mounting base 34 moving along with the conveyance mechanism 2, the vertical rod 332 can move along the unlocking inclined surface 411, thereby driving the locking block 31 to move away from the carrier 5. When the vertical rod 332 reaches a boundary between the unlocking inclined surface 411 and the pressing flat surface 412, the vertical rod 332 can reach the end of the obround slot 341 that is away from the carrier 5. In this case, the locking block 31 no longer abuts against the carrier 5, and the carrier 5 is in an unlocked state.

The pressing flat surface 412 remains a flat surface in the product conveyance direction. After the vertical rod 332 reaches the pressing flat surface 412 along the unlocking inclined surface 411, the vertical rod 332 remains pressed against the pressing flat surface 412, thereby ensuring that the locking block 31 remains in a state of not abutting against the carrier 5.

In some embodiments, the carrier unlocking mechanism 4 may alternatively be disposed at the inlet of the product channel 14. At the inlet of the product channel 14, along with the conveyance of the conveyance mechanism 2, the vertical rod 332 first contacts the pressing flat surface 412 of the carrier unlocking mechanism 4, and then contacts the unlocking inclined surface 411 of the carrier unlocking mechanism 4. At the outlet of the product channel 14, the vertical rod 332 first contacts the unlocking inclined surface 411 of the carrier unlocking mechanism 4 and then contacts the pressing flat surface 412 of the carrier unlocking mechanism 4.

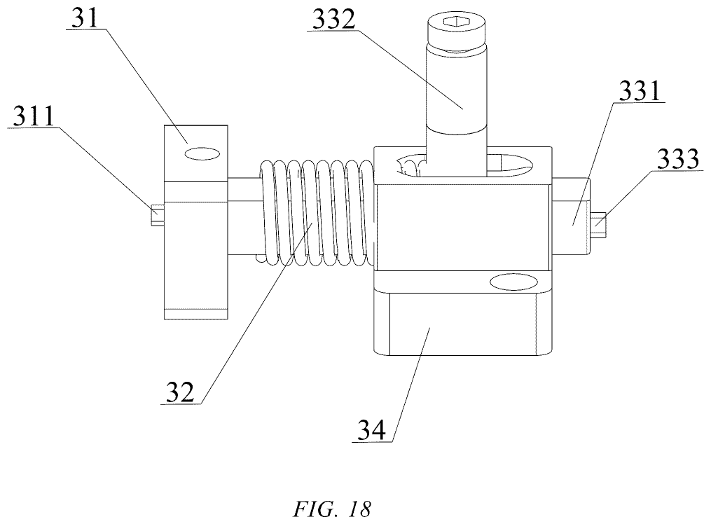

Referring to FIG. 18, in some embodiments, the plate body 41 is no longer provided with the unlocking surface, and the plate body 41 is made of a magnetic material to make the plate body 41 magnetic. An end of the pull rod 331 that is close to plate body 41 is connected to a magnet 333. When the pull rod 331 reaches an attraction position of the plate body 41, the plate body 41 can attract the magnet 333 to enable the pull rod 331 to move toward the plate body 41 until the magnet 333 is pressed against the plate body 41. In this case, the locking block 31 locks the carrier 5. When the pull rod 331 is disengaged from the attraction position of the plate body 41, the plate body 41 no longer attracts the magnet 333. The locking block 31 is reset through the elastic member 32, to enable the carrier 5 to be in an unlocked state. Both the plate body 41 and the magnet 333 are made of magnetic materials, so that the plate body 41 has a simpler overall structure, and is easier to process. Preferably, the elastic member 32 is disposed to make an attraction force between the magnet 333 and the plate body 41 balance with the elastic force of the elastic member 32, so that while the magnet 333 does not need to contact the plate body 41, the locking block 31 can also lock the carrier 5, to avoid the sliding friction between the magnet 333 and the plate body 41, thereby extending the service life of the magnet 333 and the plate body 41.

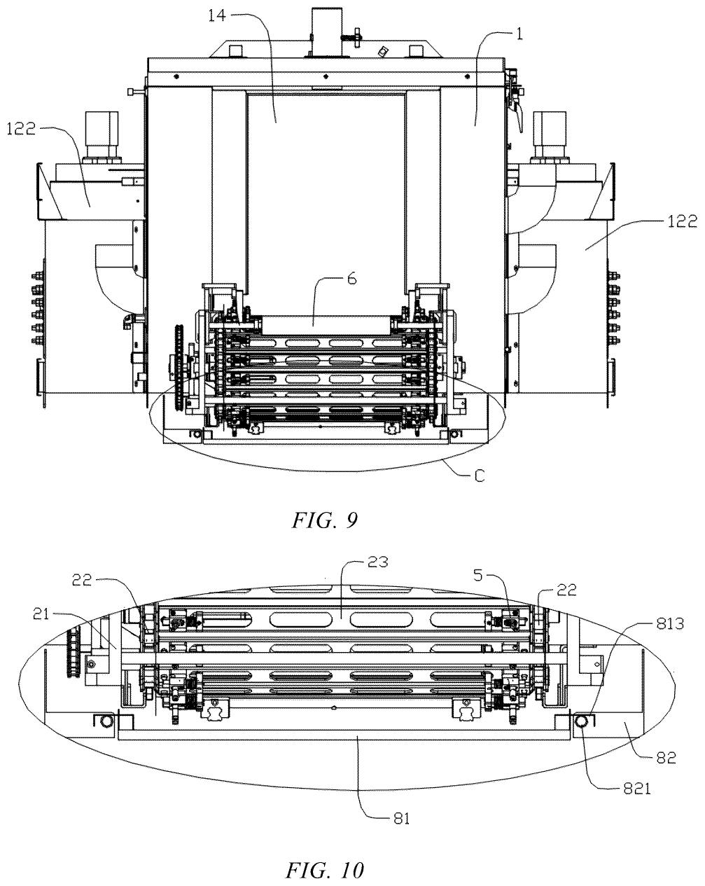

Because the conveyance mechanism 2 is a racetrack-shaped closed-loop structure formed by a closed-loop chain 22 and the support plates 23, both the inlet and the outlet of the product channel 14 are end portions of the racetrack-shaped closed-loop structure that have large curvature, and are prone to unstable carrier placement. Therefore, in some embodiments, referring to FIG. 2 and FIG. 9, transfer roller sets 6 used for bearing the carrier 5 are respectively provided close to the inlet and the outlet of the product channel 14 on the conveyance rack 21. The transfer roller set 6 includes at least two transfer rollers, upper end surfaces of all the transfer rollers are located in a same plane, and the upper end surface of the transfer roller closest to the inlet or outlet of the product channel is flush with an end surface for bearing the carrier of the conveyance mechanism 2.

When the product is transferred to a next process stage from the outlet of the product channel 14, an empty carrier 5 remains on the conveyance mechanism 2. To recycle or temporarily store the empty carrier 5, in some embodiments, a carrier recirculation mechanism 7 used for conveying the carrier 5 is provided below the furnace body 1. Furthermore, a lifting mechanism used for lifting the carrier 5 onto the conveyance mechanism 2 is provided between the conveyance mechanism 2 close to the inlet of the product channel 14 and the carrier recirculation mechanism 7. The carrier recirculation mechanism 7 enables the carrier at the outlet of the product channel 14 to recirculate to the inlet of the product channel 14, and then the lifting mechanism lifts the carrier 5 on the carrier recirculation mechanism 7 onto the conveyance mechanism 2, thereby facilitating the loading of a next product.

Specifically, the carrier recirculation mechanism 7 includes at least three conveyance mechanisms. The conveyance mechanisms may be considered as belt conveyor devices. Conveyance paths of the three conveyance mechanisms are located at the same straight line and are in communication with each other. Each conveyance structure is driven by an independent motor, so that the position of the carrier 5 on the carrier recirculation mechanism 7 can be flexibly controlled, so that a particular distance exists between a plurality of carriers 5, thereby avoiding collision between the carriers 5.

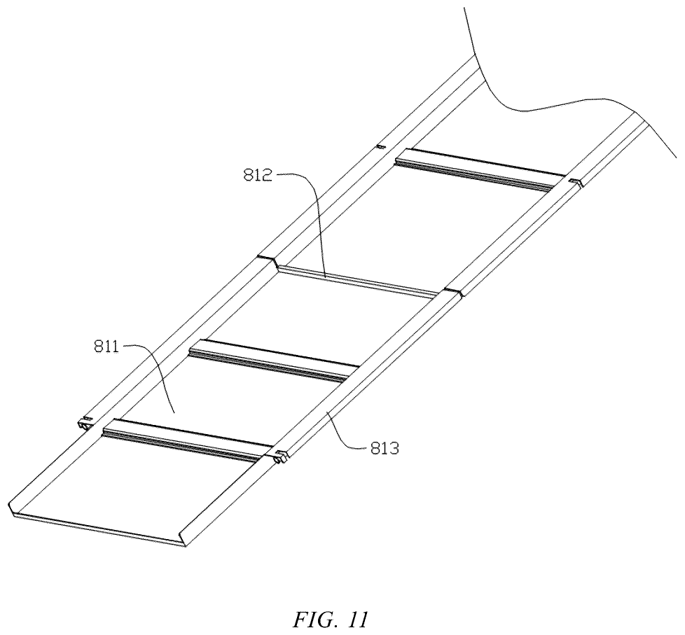

In the operation process of the conveyance mechanism 2, the continuous transmission friction of the closed-loop chain 22 generates metal dust. The metal dust may falls on the carrier 5 of the carrier recirculation mechanism 7, and when a product is loaded on the carrier 5 again, the product may be contaminated. Based on this, in some embodiments, referring to FIG. 9 and FIG. 10, the furnace body 1 is further provided with a dust collection mechanism located between the conveyance mechanism 2 and the carrier recirculation mechanism 7. The dust collection mechanism includes a dust case 81 with an opening upwards. The dust case 81 extends in the product conveyance direction. A width (the width is a dimension in the direction perpendicular to the product conveyance direction) of the dust case 81 is greater than a width of the conveyance mechanism 2.

Specifically, referring to FIG. 10 and FIG. 11, the dust case 81 includes a plurality of case bodies 811 arranged in sequence in the product conveyance direction. Any two adjacent case bodies 811 are joined and fixed by a connecting plate 812. Through the joining of the plurality of case bodies 811, the length of the dust case 81 may be flexibly adjusted according to actual operating conditions. Furthermore, the connecting plate 812 and the case body 811 can be fixedly connected through welding, insertion or threads.

In some embodiments, the dust collection mechanism further includes mounting plates 82 symmetrically disposed on two sides of the dust case 81. Each of the mounting plate 82 is an “L”-shaped structure, and is fixedly connected to the furnace body 1, and the mounting plates 82 is provided with a support rod 821 extending in the product conveyance direction. A support cover plate 813 that can be hung on the support rod 821 is integrally disposed on each of two sides of the case body 811. The cooperation of the support cover plate 813 and the support rod 821 ensures the stable support for the dust case 81 by the support rod 821 is, and can facilitate the detachment of the support cover plate 813 and the support rod 821, thereby facilitating timely removal of dust accumulated on the case body 811.

The foregoing embodiments are only used to describe the technical concept and characteristics of the present invention, and are intended to enable a person skilled in the art to understand the content of the present invention and achieve implementation, but shall not be used to limit the protection scope of the present invention. Any equivalent variations or modifications made according to the spirit and essence of the present invention shall fall within the protection scope of the present invention.

What is claimed is:

1. A heat treatment furnace with stable conveyance, comprising:
a furnace body, wherein the furnace body is provided with an isolation zone, a drying zone, and a cooling zone in sequence in a product conveyance direction, the isolation zone, the drying zone, and the cooling zone are jointly provided with a product channel which extends through the furnace body, the drying zone comprises at least one drying box body disposed in sequence, and circulating heating modules used for heating the product channel are symmetrically disposed on two sides of each drying box body;
a conveyance mechanism, used for conveying a product in the product channel, wherein the conveyance mechanism comprises a carrier bearing surface used for bearing a carrier, and the carrier is loaded with at least one product;
a carrier locking mechanism, arranged on the carrier bearing surface, and used for locking the carrier on the carrier bearing surface; and
a carrier unlocking mechanism, at least arranged at an outlet of the product channel, and used for releasing the locking of the carrier by the carrier locking mechanism.

2. The heat treatment furnace with stable conveyance according to claim 1, wherein each of the circulating heating modules comprises a heating chamber, a circulating air passage, and a suction assembly, a heating member is provided in the heating chamber, and the circulating air passage is used for connecting the heating chamber and the product channel; and the suction assembly is arranged at a top of the heating chamber, and is used for suctioning the heating chamber, to enable airflow in the heating chamber to circulate in the circulating air passage and the product channel.

3. The heat treatment furnace with stable conveyance according to claim 2, wherein the circulating air passage comprises a first air passage and a second air passage that are used cooperatively, the first air passage extends through a side wall of the drying box body, and the second air passage is sandwiched between an inner bottom wall and an outer bottom wall of the drying box body; and when the suction assembly is started, the first air passage guides the corresponding airflow in the heating chamber into the product channel, and the second air passage recirculates the airflow in the product channel into the corresponding heating chamber.

4. The heat treatment furnace with stable conveyance according to claim 3, wherein two second air passages are separated by a partition plate, a recirculation opening in communication with the two second air passages is opened on the inner bottom wall of the drying box body, the recirculation opening is covered with a second mesh plate which is fixedly connected to the inner bottom wall of the drying box body, the partition plate is disposed vertically, and an upper end of the partition plate is connected to a middle of the second mesh plate.

5. The heat treatment furnace with stable conveyance according to claim 1, wherein the carrier locking mechanism comprises a plurality of locking portions arranged on the carrier bearing surface in the product conveyance direction, each of the locking portions comprises locking assemblies symmetrically disposed in a direction perpendicular to the product conveyance direction, each of the locking assemblies comprises a locking block, an elastic member, and a movable member, the movable member is reciprocally movable in the direction perpendicular to the product conveyance direction, the locking block is connected to a side of the movable member that faces the carrier, the elastic member is located on a side of the locking block that is away from the carrier, one end of the elastic member abuts against the locking block, and the other end of the elastic member is fixed on the carrier bearing surface; and when the locking block abuts against the carrier, the elastic member is in a compressed state.

6. The heat treatment furnace with stable conveyance according to claim 5, wherein the locking assembly further comprises a mounting base, and the mounting base is fixedly connected to the conveyance mechanism, and a guide slot extends through the mounting base; the movable member comprises a pull rod passing through the guide slot, and an end of the pull rod that faces the carrier is connected to the locking block; and the elastic member comprises a spring sleeved over the pull rod, one end of the spring abuts against the locking block, and the other end of the spring abuts against the mounting base.

7. The heat treatment furnace with stable conveyance according to claim 5, wherein a locking protrusion is provided on a side of the locking block that faces the carrier; when the locking block abuts against the carrier, a lower end surface of the locking protrusion also abuts against the carrier; and the lower end surface of the locking protrusion is a downward-arching arc-shaped surface.

8. The heat treatment furnace with stable conveyance according to claim 7, wherein the carrier unlocking mechanism comprises unlocking assemblies symmetrically disposed on the conveyance mechanism in the direction perpendicular to the product conveyance direction, each of the unlocking assemblies comprises a plate body arranged in the product conveyance direction, and an unlocking surface capable of pressing against the movable member is provided on a side of the plate body that is away from the carrier; and when the carrier moves to the carrier unlocking mechanism, the movable member is movable away from the carrier under the action of the unlocking surface, to disengage the locking block from the carrier.

9. The heat treatment furnace with stable conveyance according to claim 1, wherein a carrier recirculation mechanism used for conveying the carrier is provided below the furnace body, and a lifting mechanism used for lifting the carrier onto the conveyance mechanism is provided between the conveyance mechanism that is close to an inlet of the product channel and the carrier recirculation mechanism; and the furnace body is further provided with a dust collection mechanism located between the conveyance mechanism and the carrier recirculation mechanism, the dust collection mechanism comprises a dust case with an opening upwards, the dust case extends in the product conveyance direction, and a width of the dust case is greater than a width of the conveyance mechanism.

10. The heat treatment furnace with stable conveyance according to claim 1, wherein a transfer roller set used for bearing the carrier is provided close to an inlet of the product channel, the transfer roller set comprises at least two transfer rollers, upper end surfaces of the transfer rollers are located in a same plane, and the upper end surface of the transfer roller closest to the inlet of the product channel is flush with an end surface for bearing the carrier of the conveyance mechanism.

11. The heat treatment furnace with stable conveyance according to claim 1, wherein a thermal conductive member is connected to a side wall of the product channel, the thermal conductive member is located in the isolation zone and/or the cooling zone, and the thermal conductive member is connected to a ventilation duct extending toward the drying zone.

12. The heat treatment furnace with stable conveyance according to claim 1, wherein an air curtain is connected to a side wall of the product channel, the air curtain is provided with an internal channel, the air curtain is further provided with a ventilation opening in a radial direction of the product channel, the ventilation opening is in communication with the internal channel, an air blowing member is further connected to the air curtain, and an output end of the air blowing member is in communication with the internal channel.
